(19) United States
(12) Patent Application Publication
(10) Pub. No.: US 2024/0378504 A1
(43) Pub. Date: Nov. 14, 2024

(54) METHOD AND DEVICE FOR PREDICTING LIGHT OUTPUT OF NITRIDE SEMICONDUCTOR LIGHT-EMITTING ELEMENT

(71) Applicant: NIKKISO CO., LTD., Tokyo (JP)

(72) Inventors: Ryu NAKAJIMA, Ishikawa (JP); Yusuke MATSUKURA, Ishikawa (JP); Naoki SHIBATA, Ishikawa (JP); Shinya FUKAHORI, Ishikawa (JP); Cyril PERNOT, Ishikawa (JP)

(73) Assignee: NIKKISO CO., LTD., Tokyo (JP)

(21) Appl. No.: 18/657,964

(22) Filed: May 8, 2024

(30) Foreign Application Priority Data
May 9, 2023 (JP) 2023-077204
Oct. 26, 2023 (JP) 2023-183939

(51) Int. Cl. G06N 20/00; G06N 5/022; H01L 33/06; H01L 33/32

(52) U.S. Cl. CPC G06N 20/00; G06N 5/022; H01L 33/06; H01L 33/32

(57) ABSTRACT

A light output prediction method for nitride semiconductor light-emitting element that is a method for predicting light output of a nitride semiconductor light-emitting element, the method including a model creation step of creating a trained model by learning at least a correlation of at least one of a composition parameter or a physical property parameter of a layer constituting the nitride semiconductor light-emitting element and a manufacturing condition parameter, relative to light output of the nitride semiconductor light-emitting element; and a light output prediction step of predicting light output using the trained model. In the model creation step, at least one of the composition parameter or the physical property parameter of a predetermined layer of the nitride semiconductor light-emitting element is used for the learning, and a growth temperature of the predetermined layer is used as the manufacturing condition parameter for the learning.

### CROSS-REFERENCE TO RELATED APPLICATIONS

The present application is based on Japanese patent application No. 2023-077204 filed on May 9, 2023 and Japanese patent application No. 2023-183939 filed on Oct. 26, 2023, respectively, the entire contents of which are incorporated herein by reference.

### TECHNICAL FIELD

The present invention relates to a method and device for predicting light output of nitride semiconductor light-emitting element.

### BACKGROUND OF THE INVENTION

Group III nitride semiconductors made of compounds of aluminum (Al), gallium (Ga), indium (In), etc., and nitrogen (N) are used as materials for ultraviolet light-emitting elements. Of those, group III nitride semiconductors made of AlGaN with a high Al composition are used for ultraviolet light-emitting elements and deep ultraviolet light-emitting elements (see, e.g., Patent Literature 1).

Prior art document information related to the invention of the present application includes Patent Literature 2. Patent Literature 2 proposes a prediction method using machine learning to efficiently predict the characteristics of films deposited by a film deposition apparatus.

### CITATION LIST

Patent Literature 1: Japanese Patent No. 6001756
Patent Literature 2: Japanese Patent No. 6959191

### SUMMARY OF THE INVENTION

To produce nitride semiconductor light-emitting elements, cutting into chips and packaging are required after film deposition, hence, it takes a long time to become finished products. This causes a problem in that when, e.g., the design for film deposition is revised, it takes a very long time to repeat prototyping and evaluation. Therefore, it is desired to predict light output of nitride semiconductor light-emitting elements before prototyping. However, nitride semiconductor light-emitting elements require the control of a very large number of parameters, and it is unclear what parameters should be used to predict light output.

Therefore, it is an object of the invention to provide a method and device for predicting light output of nitride semiconductor light-emitting element, which are capable of predicting light output of a nitride semiconductor light-emitting element.

A light output prediction method for nitride semiconductor light-emitting element in an embodiment of the invention is a method for predicting light output of a nitride semiconductor light-emitting element, the method comprising:
a model creation step of creating a trained model by learning at least a correlation of at least one of a composition parameter or a physical property parameter, and a manufacturing condition parameter, relative to light output of the nitride semiconductor light-emitting element, the composition parameter being a parameter defining a composition of a layer constituting the nitride semiconductor light-emitting element, the physical property parameter being a parameter defining physical properties of the layer constituting the nitride semiconductor light-emitting element, and the manufacturing condition parameter being a condition for manufacturing the nitride semiconductor light-emitting element that is changed when adjusting a value of the composition parameter or the physical property parameter; and
a light output prediction step of predicting light output using the trained model, wherein in the model creation step, at least one of the composition parameter or the physical property parameter of a predetermined layer of the nitride semiconductor light-emitting element is used for the learning, and a growth temperature of the predetermined layer is used as the manufacturing condition parameter for the learning.

Moreover, a light output prediction device for nitride semiconductor light-emitting element in the embodiment of the invention is a device to predict light output of a nitride semiconductor light-emitting element, the device comprising:
a model creation unit that creates a trained model by learning at least a correlation of at least one of a composition parameter or a physical property parameter, and a manufacturing condition parameter, relative to light output of the nitride semiconductor light-emitting element, the composition parameter being a parameter defining a composition of a layer constituting the nitride semiconductor light-emitting element, the physical property parameter being a parameter defining physical properties of the layer constituting the nitride semiconductor light-emitting element, and the manufacturing condition parameter being a condition for manufacturing the nitride semiconductor light-emitting element that is changed when adjusting a value of the composition parameter or the physical property parameter; and
a light output prediction unit that predicts light output using the trained model, wherein the model creation unit uses at least one of the composition parameter or the physical property parameter of a predetermined layer of the nitride semiconductor light-emitting element for the learning, and also uses a growth temperature of the predetermined layer as the manufacturing condition parameter for the learning.

### Advantageous Effects of the Invention

According to the invention, it is possible to provide a method and device for predicting light output of nitride semiconductor light-emitting element, which are capable of predicting light output of a nitride semiconductor light-emitting element.

### BRIEF DESCRIPTION OF DRAWINGS

FIG. 1 is a schematic diagram illustrating a configuration of a nitride semiconductor light-emitting element.

FIG. 2 is a schematic configuration diagram illustrating a light output prediction device for nitride semiconductor light-emitting element in an embodiment of the present invention.

FIG. 3A is a diagram illustrating an example of training data.

FIG. 3B is a diagram illustrating an example of training data.

FIGS. 4A and 4B are graphs obtained when a growth temperature of a well layer is changed while maintaining an Al composition ratio of the well layer fixed, wherein FIG. 4A is a diagram illustrating a change in wavelength and FIG. 4B is a diagram illustrating a change in light output.

FIGS. 5A and 5B are graphs obtained when a growth temperature of a buffer layer is changed while maintaining a film thickness of the buffer layer fixed, wherein FIG. 5A is a diagram illustrating a change in the film thickness of the buffer layer and FIG. 5B is a diagram illustrating a change in light output.

FIG. 6 is an explanatory diagram illustrating a model creation step.

FIG. 7 is an explanatory diagram illustrating a light output prediction step.

FIG. 8 is an explanatory diagram illustrating a control flow of a method for predicting light output of a nitride semiconductor light-emitting element in the embodiment of the invention.

### DETAILED DESCRIPTION OF THE INVENTION

### Embodiment

An embodiment of the invention will be described below in conjunction with the appended drawings.

### Nitride Semiconductor Light-Emitting Element 100

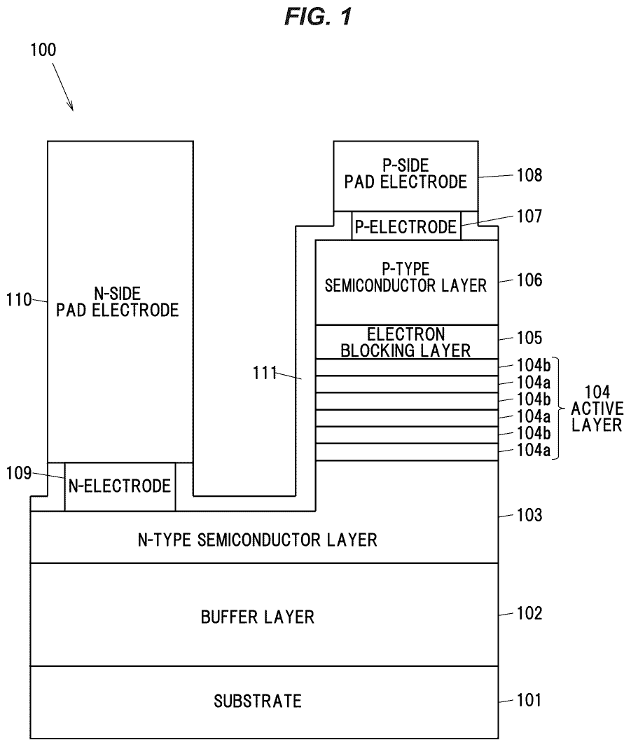

First, a nitride semiconductor light-emitting element 100 (hereinafter, also simply referred to as the “light-emitting element 100”) whose light output is to be predicted in the present embodiment will be described. FIG. 1 is a schematic diagram illustrating a configuration of the nitride semiconductor light-emitting element 100. In FIG. 1, the scale ratio in a direction of stacking each layer of the light-emitting element 100 is not necessarily the same as the actual scale ratio, and each layer may have a multilayer structure.

The light-emitting element 100 is a light-emitting diode (LED) and, in the present embodiment, emits light with a wavelength in an ultraviolet region. The light-emitting element 100 is, e.g., a deep ultraviolet LED which emits ultraviolet light at a central wavelength of not less than 200 nm and not more than 365 nm, and is used for, e.g., sterilization of water or air, etc.

As shown in FIG. 1, the light-emitting element 100 includes a buffer layer 102, an n-type semiconductor layer 103, an active layer 104, an electron blocking layer 105, and a p-type semiconductor layer 106 in this order on a substrate 101. A p-type electrode 107 and a p-side pad electrode 108 are provided in this order on the p-type semiconductor layer 106, and an n-type electrode 109 and an n-side pad electrode 110 are provided in this order on the n-type semiconductor layer 103. In addition, a passivation film (protective film) 111 is provided on side surfaces of the p-type electrode 107 and the n-type electrode 109 and on the surface of the light-emitting element 100 between the p-type electrode 107 and the n-type electrode 109. The active layer 104 has a multi-quantum well (MQW) structure in which barrier layers 104a and well layers 104b are alternately stacked.

Each of the layers 102 to 106 on the substrate 101 can be formed using a well-known epitaxial growth method such as Metal Organic Chemical Vapor Deposition (MOCVD) method, Molecular Beam Epitaxy (MBE) method, or Hydride Vapor Phase Epitaxy (HVPE) method, etc.

As semiconductors constituting the light-emitting element 100, it is possible to use, e.g., binary to quaternary group III nitride semiconductors expressed by AlₓGa_{y}In_{1-x-y}N (0≤x≤1, 0≤y≤1, 0≤x+y≤1). For deep ultraviolet LEDs, Al_{z}Ga_{1-z}N-based semiconductors (0≤z≤1), which do not contain indium, are often used. The group III elements of semiconductors constituting the light-emitting element 100 may be partially substituted with boron (B) or thallium (TI), etc. In addition, nitrogen may be partially substituted with phosphorus (P), arsenic (As), antimony (Sb) or bismuth (Bi), etc. In the present embodiment, each of the layers 102 to 106 is made of Al_{z}Ga_{1-z}N (0≤z≤1).

The structure in FIG. 1 is only an example, and the specific structure of the light-emitting element 100 is not limited to that shown in the drawing and can be changed as appropriate.

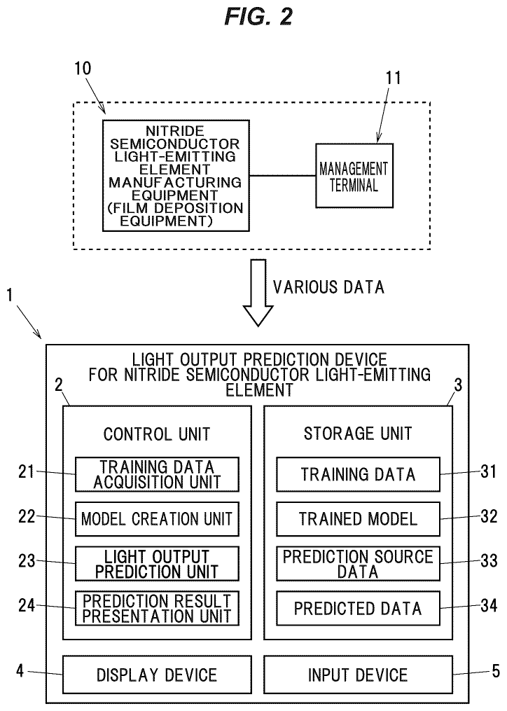

Light output prediction device 1 for nitride semiconductor light-emitting element FIG. 2 is a schematic configuration diagram illustrating a light output prediction device 1 for nitride semiconductor light-emitting element (hereinafter, simply referred to as the “light output prediction device 1”). In FIG. 2, a nitride semiconductor light-emitting element manufacturing equipment 10 (film deposition equipment) and a management terminal 11 are shown together with the light output prediction device 1. The nitride semiconductor light-emitting element manufacturing equipment 10 is an apparatus to deposit each of the layers 102 to 106 of the light-emitting element 100 using a well-known epitaxial growth method such as the metal organic chemical vapor deposition method, the molecular beam epitaxy method, or the hydride vapor phase epitaxy method. The management terminal 11 is a terminal device to manage the nitride semiconductor light-emitting element manufacturing equipment 10 and is composed of, e.g., a personal computer, etc. In this regard, the management terminal 11 can be omitted, and the light output prediction device 1 may have a function as the management terminal 11.

As shown in FIG. 2, the light output prediction device 1 includes a control unit 2, a storage unit 3, a display device 4, and an input device 5. The light output prediction device 1 is composed of, e.g., a computing device such as personal computer or server device.

The control unit 2 has a training data acquisition unit 21, a model creation unit 22, a light output prediction unit 23, and a prediction result presentation unit 24. The details of each unit will be described later. The control unit 2 is realized by appropriately combining an arithmetic element, a memory, an interface and a storage device, etc. The storage unit 3 is realized by a predetermined storage area of a memory or storage device and stores data, etc. used for various controls by the control unit 2 described later. The input device 5 is composed of, e.g., a keyboard or a mouse, etc. The display device 4 is composed of, e.g., a liquid crystal display, etc.

### Training Data Acquisition Unit 21

The training data acquisition unit 21 performs processing to acquire various data to be used for learning (machine learning) from the outside and store the data as training data 31 in the storage unit 3. The various data may be directly acquired from the nitride semiconductor light-emitting element manufacturing equipment 10 through wired or wireless communication, or may be acquired from the management terminal 11 through wired or wireless communication. The various data may be input from the input device 5, and may be input using, e.g., a medium such as a USB memory stick. In this way, the method for acquiring the training data 31 is not particularly limited.

### Training Data 31 and Parameters Used for Machine Learning

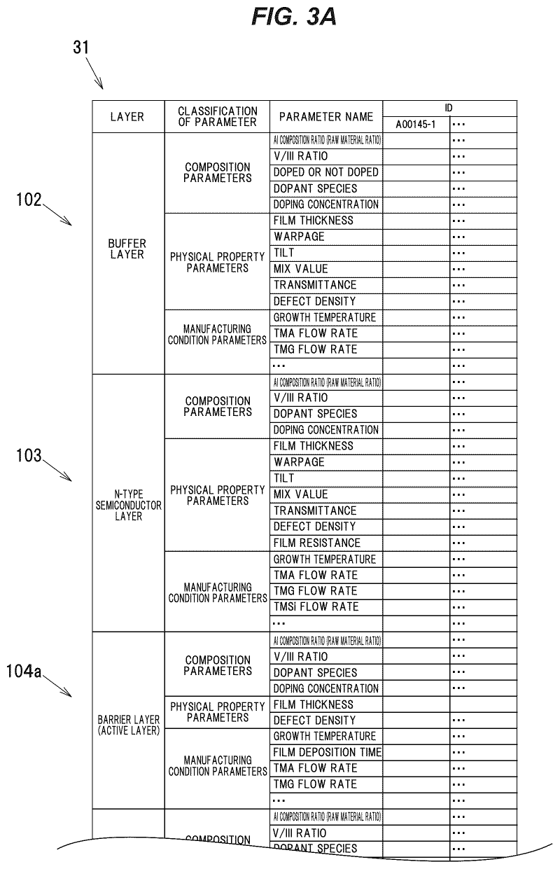

Here, an example of the training data 31 used for machine learning will be explained. FIGS. 3A and 3B are diagrams illustrating an example of the training data 31. As shown in FIGS. 3A and 3B, in the stored training data 31, data corresponding to composition parameters, physical property parameters and manufacturing condition parameters of each of the layers 102 to 106 are associated with light output data. The composition parameters are parameters that define the composition of each of the layers 102 to 106 constituting the light-emitting element 100. The physical property parameters are parameters that define the physical properties (and physical structure, etc.) of each of the layers 102 to 106 constituting the light-emitting element 100. The manufacturing condition parameters are parameters that define the conditions for manufacturing the light-emitting element 100.

In this regard, the specific parameters for the composition parameters, the physical property parameters and the manufacturing condition parameters are not limited to those shown in the drawings, and other parameters may be used. In addition, the training data 31 may include parameters other than the composition parameters, the physical property parameters and the manufacturing condition parameters, and may include, e.g., equipment state parameters representing the state of the nitride semiconductor light-emitting element manufacturing equipment 10. Examples of the equipment state parameter include height of deposit on the tray, the number of pockets, temperature of the chiller or cooling water and the flow rate, the number of times of film depositions, and furnace dimensions, etc. In addition to the above parameters, the training data 31 may also include substrate parameters representing the state, etc. of the substrate 101, or electrode parameters representing the states, etc. of the electrodes 107 to 110, etc. The manufacturing condition parameters are not essential and can be omitted. Moreover, the training data 31 may be data that include only one of the composition parameter and the physical property parameter.

Although the details will be described later, a relationship between the light output and each of the composition, physical property and manufacturing condition parameters is machine-learned in the present embodiment. Therefore, it is desirable that parameters having a large impact on the light output be selected as the composition parameter and the physical property parameter used for machine learning. When the manufacturing condition parameter is used for machine learning, it is desirable to select a parameter that is changed when adjusting a value of the composition parameter or the physical property parameter used for machine learning.

In more particular, for the buffer layer 102, it is desirable that the Al composition ratio be used as the composition parameter, and the film thickness, the transmittance and the mix value be used as the physical property parameters for machine learning. In this regard, the mix value is a full width at half maximum of X-ray rocking curve (arcsec) obtained by X-ray diffraction ω scan for a (10-12) plane (a mixed plane) of a crystal, and is a representative indicator of crystal quality of each layer of nitride semiconductor light-emitting elements. When the manufacturing condition parameters of the buffer layer 102 are used for machine learning, it is desirable that the growth temperature (heater temperature or substrate temperature), the TMA (trimethylaluminum) flow rate and the TMG (trimethylgallium) flow rate be used as the manufacturing condition parameters.

For the n-type semiconductor layer 103, it is desirable that the Al composition ratio and the doping concentration be used as the composition parameters, and the mix value, the transmittance and the film resistance be used as the physical property parameters. Particularly for the n-type semiconductor layer 103, the mix value which is the physical property parameter is considered to have a large impact on the light output and is thus desirably used for machine learning when there is variation in the data to the extent that it cannot be considered constant. When the manufacturing condition parameters of the n-type semiconductor layer 103 are used for machine learning, it is desirable that the TMA flow rate, the TMG flow rate and the TMSi (tetramethylsilane) flow rate be used as the manufacturing condition parameters.

For the barrier layers 104a of the active layer 104, it is desirable that the Al composition ratio and the doping concentration be used as the composition parameters, and the film thickness be used as the physical property parameter. Each of these Al composition ratio parameter, doping concentration parameter and film thickness parameter of the barrier layers 104a has a large impact on the light output and is thus desirably used for machine learning when there is variation in the data to the extent that it cannot be considered constant. When the manufacturing condition parameters of the barrier layers 104a are used for machine learning, it is desirable that the growth temperature (heater temperature or substrate temperature), the film deposition time, the TMA flow rate and the TMG flow rate be used as the manufacturing condition parameters.

For the well layers 104b of the active layer 104, it is desirable that the Al composition ratio and the doping concentration be used as the composition parameters, and the film thickness be used as the physical property parameter, in the same manner as the barrier layers 104a described above. Each of these Al composition ratio parameter, doping concentration parameter and film thickness parameter of the well layers 104b has a large impact on the light output and is thus desirably used for machine learning when there is variation in the data to the extent that it cannot be considered constant. When the manufacturing condition parameters of the well layers 104b are used for machine learning, it is desirable that the growth temperature (heater temperature or substrate temperature), the film deposition time, the TMA flow rate and the TMG flow rate be used as the manufacturing condition parameters.

For the electron blocking layer 105, it is desirable that the Al composition ratio be used as the composition parameter, and the film thickness and the transmittance be used as the physical property parameters. Each of these Al composition ratio parameter, film thickness parameter and transmittance parameter of the electron blocking layer 105 has a large impact on the light output and is thus desirably used for machine learning when there is variation in the data to the extent that it cannot be considered constant. When the manufacturing condition parameters of the electron blocking layer 105 are used for machine learning, it is desirable that the heater temperature, the film deposition time, the TMA flow rate and the TMG flow rate be used as the manufacturing condition parameters.

For the p-type semiconductor layer 106, it is desirable that the Al composition ratio be used as the composition parameter, and the film thickness and the transmittance be used as the physical property parameters, in the same manner as the electron blocking layer 105 described above. Each of these Al composition ratio parameter, film thickness parameter and transmittance parameter of the p-type semiconductor layer 106 has a large impact on the light output and is thus desirably used for machine learning when there is variation in the data to the extent that it cannot be considered constant. When the manufacturing condition parameters of the p-type semiconductor layer 106 are used for machine learning, it is desirable that the growth temperature (heater temperature or substrate temperature), the film deposition time, the TMA flow rate and the TMG flow rate be used as the manufacturing condition parameters.

The light output used in the present embodiment is light output of the light-emitting element 100 in a state of finished product obtained by cutting into a chip and packaging after film deposition. The light output varies also depending on various conditions in the process of cutting into chips and packaging, but in this example, the conditions for cutting into chips and packaging are assumed to be the same and are not used for machine learning. However, machine learning can be performed including the conditions for cutting into chips and packaging.

### Combined Use of Manufacturing Condition Parameter

Furthermore, the present inventors studied and found that even when the composition parameter and the physical property parameter are constant, the light output may change if the manufacturing condition parameter changes. This will be explained in detail below.

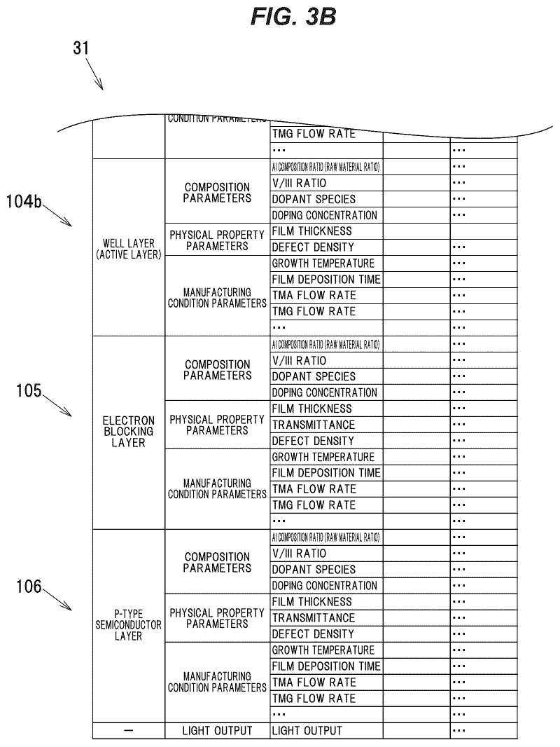

First, the growth temperature of the well layers 104b was changed while maintaining the Al composition ratio of the well layers 104b fixed. The Al composition ratio of the well layers 104b has a large impact on the light output as described above, and when the Al composition ratio of the well layers 104b changes, the light output changes. The change in wavelength in this case is shown in FIG. 4A. As shown in FIG. 4A, the wavelength of the well layer 104b is substantially constant, and regardless of the growth temperature, the Al composition ratio is substantially constant. The change in the light output in this case is shown in FIG. 4B. As shown in FIG. 4B, the light output decreases as the growth temperature of the well layers 104b increases, which shows that although the Al composition ratio, which is the composition parameter, of the well layers 104a is constant, the light output changes depending on the growth temperature of the well layers 104a.

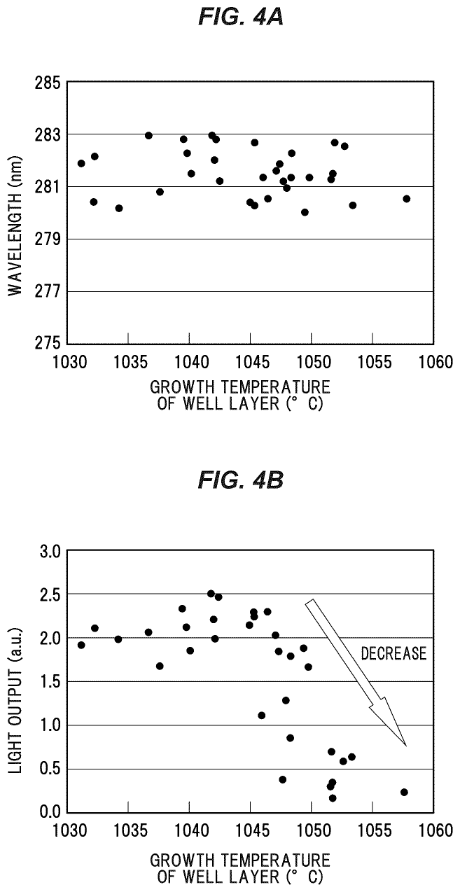

Similarly, the growth temperature of the buffer layer 102 made of AlN was changed while maintaining the film thickness of the buffer layer 102 fixed. The film thickness of the buffer layer 102 has a large impact on the light output as described above, and when the film thickness of the buffer layer 102 changes, the light output changes. The change in the film thickness of the buffer layer 102 in this case is shown in FIG. 5A. As shown in FIG. 5A, the film thickness of the buffer layer 102 is substantially constant regardless of the growth temperature. The change in the light output in this case is shown in FIG. 5B. As shown in FIG. 5B, the light output decreases as the growth temperature of the buffer layer 102 increases, which shows that although the film thickness, which is the physical property parameter, of the buffer layer 102 is constant, the light output changes depending on the growth temperature of the buffer layer 102.

In this way, in some cases, the light output cannot be predicted with sufficient accuracy only by the physical property parameter or the composition parameter. In this case, in addition to at least one of the physical property parameter and the composition parameter, the manufacturing condition parameter that is changed when adjusting the value of the composition parameter or the physical property parameter needs to be further taken into consideration to predict the light output. Based on the results of FIGS. 4A to 5B, when at least one of the composition parameter or the physical property parameter of a predetermined layer (the well layer 104a in the example of FIGS. 4A and 4B, and the buffer layer 102 in the example of FIGS. 5A and 5B) of the nitride semiconductor light-emitting element is used for learning, it is possible to accurately predict the light output of the nitride semiconductor light-emitting element 100 by using the growth temperature of this predetermined layer (the well layer 104a in the example of FIGS. 4A and 4B, and the buffer layer 102 in the example of FIGS. 5A and 5B) as the manufacturing condition parameter for the learning. For the active layer 104 (the barrier layers 104a and the well layers 104b) and the electron blocking layer 105, the film thickness is generally as thin as not more than 100 nm and it is difficult to predict the light output only by the composition parameter or the physical property parameter, hence, it is desirable to include the growth temperature as an explanatory variable. Moreover, it is more preferable to use the substrate temperature as the growth temperature. The substrate temperature can be calculated by, e.g., measuring infrared radiation emitted from the substrate surface with a pyrometer.

### Model Creation Unit 22

The model creation unit 22 performs processing to create a trained model 32 using the training data 31. The processing performed by the model creation unit 22 corresponds to the model creation step of the invention. In the present embodiment, the model creation unit 22 creates the trained model 32 by learning (machine learning) at least a correlation of at least one of the composition parameter or the physical property parameter of the layers 102 to 106 constituting the light-emitting element 100, and the manufacturing condition parameter that is changed when adjusting the value of the composition parameter or the physical property parameter, relative to the light output of the light-emitting element 100. In the present embodiment, the model creation unit 22 is configured to create the trained model 32 by using both the composition parameter and the physical property parameter for machine learning.

Alternatively, the model creation unit 22 may be configured to create the trained model 32 by machine learning of the correlation of the composition parameter, the physical property parameter and the manufacturing condition parameter relative to the light output of the nitride semiconductor light-emitting element. This allows for light output prediction that takes into account both the composition and the physical properties as well as the manufacturing condition, thereby further improving accuracy of the light output prediction.

The model creation unit 22 includes a learning algorithm which uses the composition, physical property and manufacturing condition parameters of each of the layers 102 to 106, which are set in advance, as explanatory variables and the light output as an objective variable to self-learn the correlation of each of the parameters as explanatory variables relative to the objective variable through machine learning. The learning algorithm is not particularly limited, and it is possible to use, e.g., a known learning algorithm called deep forest or deep neural network, etc.

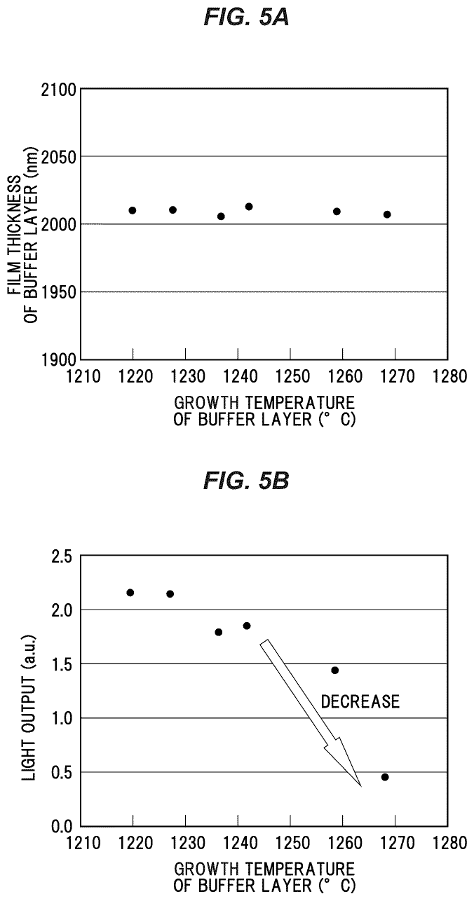

As shown in FIG. 6, the training data 31 is input to the model creation unit 22. Using the input training data 31, the model creation unit 22 iteratively performs learning based on a data set of parameters used as explanatory variables and the light output as an objective variable, automatically interprets the correlation therebetween, and creates the trained model 32. The model creation unit 22 stores the created trained model 32 in the storage unit 3. The model creation unit 22 may be configured to allow a user to appropriately select parameters (the composition parameter, the physical property parameter, the manufacturing condition parameter) to be used as explanatory variables.

### Light Output Prediction Unit 23

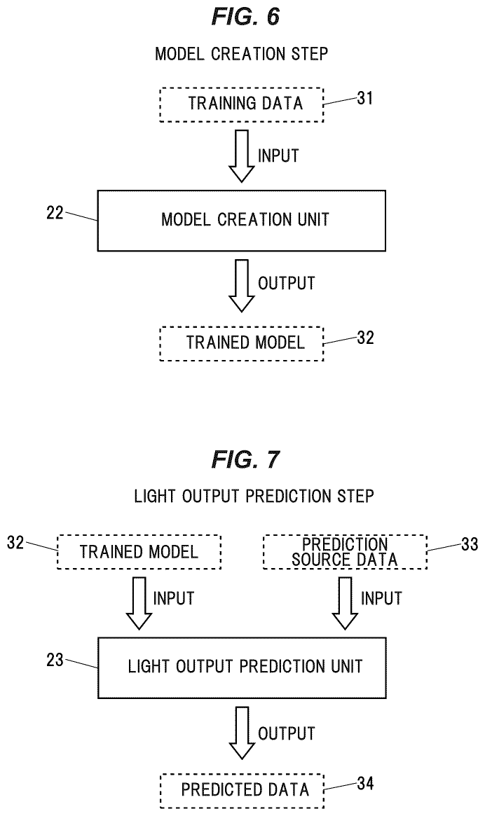

The light output prediction unit 23 performs processing to predict the light output using the trained model 32. The processing performed by the light output prediction unit 23 corresponds to the light output prediction step of the invention. As shown in FIG. 7, the trained model 32 created by the model creation unit 22 and prediction source data 33 are input to the light output prediction unit 23. The prediction source data 33 includes a value of each parameter used as an explanatory variable and is input through, e.g., the input device 5. The light output prediction unit 23 predicts the light output corresponding to the prediction source data 33 by applying the value of each parameter in the prediction source data 33 to the trained model 32. The predicted light output is stored as predicted data 34 in the storage unit 3.

### Prediction Result Presentation Unit 24

The prediction result presentation unit 24 performs processing to present the predicted data 34 predicted by the light output prediction unit 23. The prediction result presentation unit 24 presents the predicted data 34 by, e.g., displaying the predicted data 34 on the display device 4. The format of the presentation is not particularly limited and presentation may be in an appropriate format such as numerical values or graphs. However, it is not limited thereto, and the predicted data 34 may be presented by, e.g., outputting the predicted data 34 to an external device, etc.

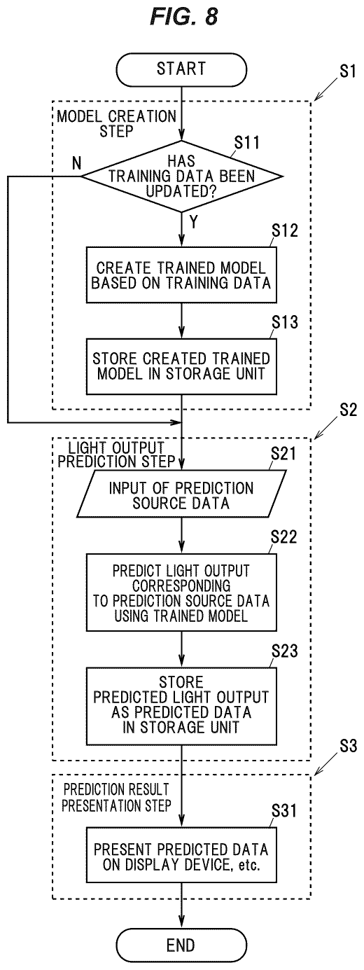

Light output prediction method for nitride semiconductor light-emitting element FIG. 8 is a flowchart showing a control flow of a light output prediction method for nitride semiconductor light-emitting element in the present embodiment. The control flow in FIG. 8 is executed when predicting the light output. Prior to the control flow in FIG. 8, the training data acquisition unit 21 acquires the training data 31 and stores the acquired training data 31 in the storage unit 3 as needed.

As shown in FIG. 8, in the light output prediction method for nitride semiconductor light-emitting element in the present embodiment, a model creation step of Step S1, a light output prediction step of Step S2, and a prediction result presentation step of Step S3 are performed sequentially.

In the model creation step of Step S1, first, in Step S11, it is determined whether the training data 31 has been updated since the last time the model creation unit 22 created the trained model 32. The determination in Step S11 can be made by comparing the creation date and time of the trained model 32 and the update date and time of the training data 31. In Step S11, in case that the trained model 32 has not been created (in case of the first time), it is determined that the training data 31 has been updated (Yes). When the determination made in Step S11 is No (N), the process proceeds to the light output prediction step of Step S2. When the determination made in Step S11 is Yes (Y), the model creation unit 22 performs machine learning on the correlation of each of the parameters set in advance as explanatory variables relative to the light output as an objective variable based on the updated training data 31, and creates the trained model 32 in Step S12.

In the present embodiment, parameters used as explanatory variables for the machine learning in Step S11 include at least one of the composition parameter or the physical property parameter of the layers 102 to 106 constituting the light-emitting element 100, and the manufacturing condition parameter of the layers 102 to 106. More preferably, the following parameters:
Al composition ratio of each of the layers 102 to 106
Transmittance of each of the layers 102, 103, 105, 106, excluding the active layer 104
Doping concentration of the barrier layer 104a, the well layer 104b, and the n-type semiconductor layer 103
Mix value of the n-type semiconductor layer 103.
Film thickness of the buffer layer 102, the barrier layer 104a, the well layer 104b, the electron blocking layer 105, and the p-type semiconductor layer 106
   are desirably included as explanatory variables when there is variation in the data to the extent that it cannot be considered constant since these parameters have a very large impact on the light output. On top of this, the growth temperature of a layer whose composition parameter or physical property parameter is used may be used as the manufacturing condition parameter. As explained with reference to FIGS. 4A and 4B, at least when the Al composition ratio of the well layer 104b is used as an explanatory variable, it is desirable to also include the growth temperature of the well layer 104b as an explanatory variable. In addition, as explained with reference to FIGS. 5A and 5B, at least when the film thickness of the buffer layer 102 is used as an explanatory variable, it is desirable to also include the growth temperature of the buffer layer 102 as an explanatory variable. Although not shown in FIG. 8, a step of selecting which parameter is use as an explanatory variable may be added before Step S12.

After creating the trained model 32 in Step S12, the model creation unit 22 stores the created trained model 32 in the storage unit 3 in Step S13, and the process proceeds to the light output prediction step of Step S2.

In the life prediction step of Step S2, first, the prediction source data 33 is input in Step S21. At this time, e.g., an input screen for inputting the prediction source data 33 may be shown on the display device 4 so that the prediction source data 33 can be input using the input device 5. When the prediction source data 33 is input in a file format, a display, etc. prompting the input of a file may be shown on the display device 4. Thereafter, in Step S22, the light output prediction unit 23 predicts the light output corresponding to the prediction source data 33 using the trained model 32 stored in the storage unit 3. Thereafter, the light output prediction unit 23 stores a value of the predicted light output as the predicted data 34 into the storage unit 3 in Step S23, and the process proceeds to the prediction result presentation step of Step S3.

In the prediction result presentation step of Step S3, the prediction result presentation unit 24 presents the light output prediction result by presenting the predicted data 34 stored in the storage unit 3 on the display device 4 in Step S31. Then, the process ends.

Although the case where the trained model 32 is updated at the time of light output prediction has been described in the present embodiment, it is not limited thereto. The model creation unit 22 may be configured to monitor the update status of the training data 31 and update the trained model 32 each time the training data 31 is updated. Alternatively, the model creation unit 22 may be configured to update the trained model 32 every predetermined period (e.g., every week or every month).

### Functions and Effects of the Embodiment

In the embodiment described above, the following functions and effects are obtained.

(1) It is possible to accurately predict the light output of the light-emitting element 100 by using the trained model 32 with the machine-learned correlation between at least one of the composition parameter or the physical property parameter of a layer constituting the light-emitting element 100, the manufacturing condition parameter that is changed when adjusting the value of the composition parameter or the physical property parameter, and the light output, and also by using the growth temperature of a predetermined layer, whose composition parameter or physical property parameter is used for learning, as the manufacturing condition parameter for learning. As a result, it is possible to predict the light output of the light-emitting element 100 without making prototypes, and development can be carried out in a short period of time without trial and error through repeated prototyping and evaluation over a long period of time.

(2) Particularly when the Al composition ratio of the well layer 104b is used as the composition parameter, the light output prediction accuracy is improved by further using the growth temperature of the well layer 104b as the manufacturing condition parameter for learning.

(3) Similarly, when the film thickness of the buffer layer 102 is used as the physical property parameter, the light output prediction accuracy is improved by further using the growth temperature of the buffer layer 102 as the manufacturing condition parameter for learning.

### Summary of the Embodiment

Technical ideas understood from the embodiment will be described below citing the reference signs, etc., used for the embodiment.

According to the first feature, a light output prediction method for nitride semiconductor light-emitting element is a method for predicting light output of a nitride semiconductor light-emitting element 100, the method comprising: a model creation step of creating a trained model 32 by learning at least a correlation of at least one of a composition parameter or a physical property parameter, and a manufacturing condition parameter, relative to light output of the nitride semiconductor light-emitting element 100, the composition parameter being a parameter defining a composition of a layer (102-106) constituting the nitride semiconductor light-emitting element 100, the physical property parameter being a parameter defining physical properties of the layer (102-106) constituting the nitride semiconductor light-emitting element 100, and the manufacturing condition parameter being a condition for manufacturing the nitride semiconductor light-emitting element 100 that is changed when adjusting a value of the composition parameter or the physical property parameter; and a light output prediction step of predicting light output using the trained model 32, wherein in the model creation step, at least one of the composition parameter or the physical property parameter of a predetermined layer of the nitride semiconductor light-emitting element 100 is used for the learning, and a growth temperature of the predetermined layer is used as the manufacturing condition parameter for the learning.

According to the second feature, in the light output prediction method for nitride semiconductor light-emitting element as described in the first feature, the nitride semiconductor light-emitting element 100 comprises an active layer 104 formed by alternately stacking barrier layers 104a and well layers 104b that comprises AlGaN, the predetermined layer is the well layer 104b, and at least an Al composition ratio of the well layer 104b, which is the composition parameter, and a growth temperature of the well layer 104b, which is the manufacturing condition parameter, are used for the learning.

According to the third feature, in the light output prediction method for nitride semiconductor light-emitting element as described in the first feature, the predetermined layer is a buffer layer 102 comprising AlN, and at least a film thickness of the buffer layer 102, which is the physical property parameter, and a growth temperature of the buffer layer 102, which is the manufacturing condition parameter, are used for the learning.

According to the fourth feature, a light output prediction device 1 for nitride semiconductor light-emitting element is a device to predict light output of a nitride semiconductor light-emitting element 100, the device comprising: a model creation unit 22 that creates a trained model 32 by learning at least a correlation of at least one of a composition parameter or a physical property parameter, and a manufacturing condition parameter, relative to light output of the nitride semiconductor light-emitting element 100, the composition parameter being a parameter defining a composition of a layer (102-106) constituting the nitride semiconductor light-emitting element 100, the physical property parameter being a parameter defining physical properties of the layer (102-106) constituting the nitride semiconductor light-emitting element 100, and the manufacturing condition parameter being a condition for manufacturing the nitride semiconductor light-emitting element 100 that is changed when adjusting a value of the composition parameter or the physical property parameter; and a light output prediction unit 23 that predicts light output using the trained model 32, wherein the model creation unit 22 uses at least one of the composition parameter or the physical property parameter of a predetermined layer of the nitride semiconductor light-emitting element 100 for the learning, and also uses a growth temperature of the predetermined layer as the manufacturing condition parameter for the learning.

### ADDITIONAL NOTE

Although the embodiment of the invention has been described, the invention according to claims is not to be limited to the embodiment described above. Further, please note that not all combinations of the features described in the embodiment are necessary to solve the problem of the invention. In addition, the invention can be appropriately modified and implemented without departing from the gist thereof.

1. A light output prediction method for nitride semiconductor light-emitting element that is a method for predicting light output of a nitride semiconductor light-emitting element, the method comprising:
a model creation step of creating a trained model by learning at least a correlation of at least one of a composition parameter or a physical property parameter, and a manufacturing condition parameter, relative to light output of the nitride semiconductor light-emitting element, the composition parameter being a parameter defining a composition of a layer constituting the nitride semiconductor light-emitting element, the physical property parameter being a parameter defining physical properties of the layer constituting the nitride semiconductor light-emitting element, and the manufacturing condition parameter being a condition for manufacturing the nitride semiconductor light-emitting element that is changed when adjusting a value of the composition parameter or the physical property parameter; and
a light output prediction step of predicting light output using the trained model,
wherein in the model creation step, at least one of the composition parameter or the physical property parameter of a predetermined layer of the nitride semiconductor light-emitting element is used for the learning, and a growth temperature of the predetermined layer is used as the manufacturing condition parameter for the learning.

2. The method according to claim 1, wherein the nitride semiconductor light-emitting element comprises an active layer formed by alternately stacking barrier layers and well layers that comprises AlGaN, wherein the predetermined layer is the well layer, and wherein at least an Al composition ratio of the well layer, which is the composition parameter, and a growth temperature of the well layer, which is the manufacturing condition parameter, are used for the learning.

3. The method according to claim 1, wherein the predetermined layer is a buffer layer comprising AlN, and wherein at least a film thickness of the buffer layer, which is the physical property parameter, and a growth temperature of the buffer layer, which is the manufacturing condition parameter, are used for the learning.

4. A light output prediction device for nitride semiconductor light-emitting element that is a device to predict light output of a nitride semiconductor light-emitting element, the device comprising:
a model creation unit that creates a trained model by learning at least a correlation of at least one of a composition parameter or a physical property parameter, and a manufacturing condition parameter, relative to light output of the nitride semiconductor light-emitting element, the composition parameter being a parameter defining a composition of a layer constituting the nitride semiconductor light-emitting element, the physical property parameter being a parameter defining physical properties of the layer constituting the nitride semiconductor light-emitting element, and the manufacturing condition parameter being a condition for manufacturing the nitride semiconductor light-emitting element that is changed when adjusting a value of the composition parameter or the physical property parameter; and
a light output prediction unit that predicts light output using the trained model,
wherein the model creation unit uses at least one of the composition parameter or the physical property parameter of a predetermined layer of the nitride semiconductor light-emitting element for the learning, and also uses a growth temperature of the predetermined layer as the manufacturing condition parameter for the learning.
